(19) United States
(12) Patent Application Publication
(10) Pub. No.: US 2012/0079349 A1
(43) Pub. Date: Mar. 29, 2012

(54) METHOD AND APPARATUS FOR MULTI-BIT UPSET PROTECTION

(76) Inventor: Arkady Bramnik, Kiryat Motzkin (IL)

(21) Appl. No.: 12/890,579

(22) Filed: Sep. 24, 2010

(51) Int. Cl. H03M 13/05; G06F 11/10

(52) U.S. Cl. 714/763; 714/E11.034

(57) ABSTRACT

Techniques for detecting for a change to information in a line of data of a data storage device. In an embodiment, a line of data includes a first set of bits and a second set of bits, each associated with distinct reference parity evaluations. Respective update parity values are determined for the first bit set and the second bit set, each update parity value for comparison to a corresponding one of the reference parity evaluations. A change to the information in the line of data may be detected based on the comparison of reference parity values to update parity values.

### BACKGROUND

1. Technical Field

The present invention relates generally to computer systems, and more specifically to a method and apparatus for detecting an error in a data storage device.

2. Background Art

Devices including data storage structures (such as memory arrays, registers, buffers, queues, caches, etc.) are subject to corruption of stored data, including but not limited to corruption by multi-bit upset (MBU) soft errors. “Soft error” is a term that is used to describe random corruption of data in computer memory. Such corruption may be caused, for example, by particles in normal environmental radiation. More specifically, alpha particles, for example, may cause bits in electronic data to randomly “flip” in value, introducing the possibility of error into the data.

Soft error rates for integrated circuits (ICs) increase as semiconductor process technologies scale to smaller dimensions and lower operating voltages. Smaller process dimensions allow greater device densities to be achieved on the IC die. This increases the likelihood that an alpha particle or cosmic ray will strike one of the IC's voltage nodes. Lower operating voltages mean that smaller charge disruptions are sufficient to alter the logic state represented by the node voltages. Both trends point to higher soft error rates in the future. Soft errors may be corrected in a processor or other data storage-capable device only if they are detected before corrupted results are used in later data processing.

In existing technologies, a corrupt line of data may remain uncorrected if detection of a change to one bit in the line of data is masked by a change to another change to a different bit in that same line of data. For example, the parity value for a line of data may remain unchanged if an even number of bits in the line of data is flipped by a particle event or other corruption event. The trend toward increased susceptibility to MBU soft errors is just one example of how undetected corruption of stored data will more frequently affect computer performance in the future.

### BRIEF DESCRIPTION OF THE DRAWINGS

The various embodiments of the present invention are illustrated by way of example, and not by way of limitation, in the figures of the accompanying drawings and in which:

FIG. 1 is a block diagram illustrating select elements of a system according to an embodiment to detect for a change to stored data.

FIG. 2 is a block diagram illustrating select elements of a device according to an embodiment to detect for a change to information in a line of data.

FIG. 3 is a block diagram illustrating various bit set allocations for detecting a change to information in a line of data according to an embodiment.

FIG. 4 is a block diagram illustrating select elements of a data storage device to detect for a change to information in a memory array according to an embodiment.

FIG. 5 is a block diagram illustrating select elements of a method according to an embodiment for detecting a change to stored data.

### DETAILED DESCRIPTION

In the following description, reference is made to the accompanying drawings which form a part hereof and which illustrate several embodiments. It is understood that other embodiments may be utilized and structural and operational changes may be made.

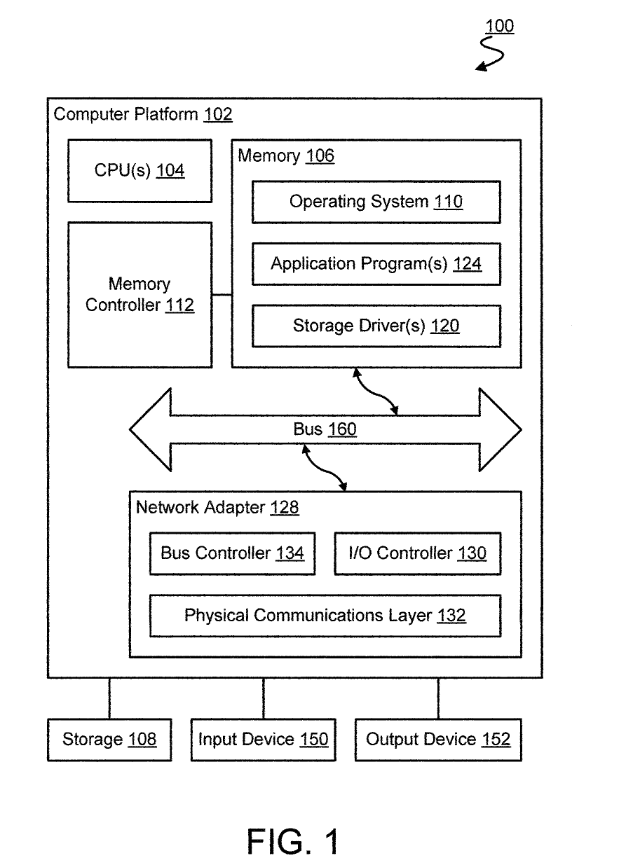

FIG. 1 illustrates select elements of a computing environment 100 for which parity information is determined in accordance with certain embodiments. Computing environment 100 is illustrative of a system including one or more components capable of determining parity information used to detect for a change to information in a line of data—e.g. where the line of data is itself in one of the components of computing environment 100. It is understood that the components and architecture shown in computing environment 100 is merely illustrative, and that computing environment 100 may include any of a variety of additional or alternate components and/or architecture to implement the techniques discussed herein.

A host computer platform 102 of computing environment 100 may include one or more central processing units (CPUs) 104, a memory controller 112, and a memory 106 controlled by memory controller 112, in which reside an operating system 110, one or more storage drivers 120 and one or more application programs 124 for execution by CPUs 104. The one or more storage drivers 120 are capable of transmitting and retrieving packets from a non-volatile storage 108 (e.g., magnetic disk drives, optical disk drives, a tape drive, etc.) of computing environment 100. It is understood that memory 106 and non-volatile storage 108 are both types of data storage, at least insofar as they are variously capable of storing some data which is available for later access. Similarly, CPU 104 and/or memory controller 112 may include one or more queues, caches, buffers, etc. which qualify CPU 104 and/or memory controller 112 as a data storage device.

The host computer platform 102 may comprise any computing device known in the art, such as a mainframe, server, personal computer, workstation, laptop, handheld computer, telephony device, network appliance, virtualization device, storage controller, etc. Any CPU 104 and operating system 110 known in the art may be used. Programs and data in memory 106 may be swapped into storage 108 as part of memory management operations. Storage 108 may be coupled to computer platform 102 via any type of network or any type of bus interface known in the art. The network may be, for example, a Storage Area Network (SAN), a Local Area Network (LAN), Wide Area Network (WAN), the Internet, an Intranet, etc. The bus interface may be, for example, any type of Peripheral Component Interconnect (PCI) bus (e.g., a PCI bus (PCI Special Interest Group, PCI Local Bus Specification, Rev 2.3, published March 2002), a PCI-X bus (PCI Special Interest Group, PCI-X 2.0a Protocol Specification, published 2002), or a PCI Express bus (PCI Special Interest Group, PCI Express Base Specification 1.0a, published 2002)), a Small Computer System Interface (SCSI) (American National Standards Institute (ANSI) SCSI Controller Commands-2 (SCC-2) NCITS.318:1998), Serial ATA (SATA 1.0a Specification, published Feb. 4, 2003), etc.

Host computer platform 102 may further include one or more network adapters 128—e.g. coupled to memory 106 via a bus 160. Each network adapter 128 includes various components implemented in the hardware of the network adapter 128. Each network adapter 128 is capable of transmitting and receiving packets of data directly or indirectly to a network. Network adapter 128 may also include one or more data storage structures.

Storage driver 120 may include network adapter 128 specific commands to communicate with network adapter 128 and interface between the operating system 110 and network adapter 128. Network adapter 128 or storage driver 120 may implement logic to process packets, such as a transport protocol layer to process the content of messages included in the packets that are wrapped in a transport layer, such as Transmission Control Protocol (TCP) (IETF RFC 793, published September 1981) and/or Internet Protocol (IP) (IETF RFC 791, published September 1981), the Internet Small Computer System Interface (iSCSI) (IETF RFC 3347, published February 2003), Fibre Channel (American National Standards Institute (ANSI) X3.269-199×, Revision 012, Dec. 4, 1995), or any other transport layer protocol known in the art. The transport protocol layer may unpack a payload from the received Transmission Control Protocol/Internet Protocol (TCP/IP) packet and transfer the data to a storage driver 120 to return to an application program 124. Further, an application program 124 transmitting data may transmit the data to a storage driver 120, which then sends the data to the transport protocol layer to package in a TCP/IP packet before transmitting over a network.

A bus controller 134 enables network adapter 128 to communicate on a computer bus 160, which may comprise any bus interface known in the art, such as a Peripheral Component Interconnect (PCI) bus (PCI Special Interest Group, PCI Local Bus Specification, Rev 2.3, published March 2002), Small Computer System Interface (SCSI) (American National Standards Institute (ANSI) SCSI Controller Commands-2 (SCC-2) NCITS.318:1998), Serial ATA ((SATA 1.0a Specification, published Feb. 4, 2003), etc. The network adapter 128 includes a network protocol for implementing a physical communication layer 132 to send and receive network packets to and from a remote network node. In certain embodiments, the network adapter 128 may implement the Ethernet protocol (IEEE std. 802.3, published Mar. 8, 2002), Fibre Channel protocol (American National Standards Institute (ANSI) X3.269-199×, Revision 012, Dec. 4, 1995) or any other network communication protocol known in the art.

The network adapter 128 includes an Input/Output (I/O) controller 130. In certain embodiments, the I/O controller 130 may comprise Internet Small Computer System Interface (iSCSI controllers), and it is understood that other types of network controllers, such as an Ethernet Media Access Controller (MAC) or Network Interface Controller (NIC), or cards may be used.

The storage 108 may comprise an internal storage device or an attached or network accessible storage. Programs in the storage 108 may be loaded into the memory 106 and executed by the CPU 104. An input device 150 is used to provide user input to the CPU 104, and may include a keyboard, mouse, pen-stylus, microphone, touch sensitive display screen, or any other activation or input mechanism known in the art. An output device 152 is capable of rendering information transferred from the CPU 104, or other component, such as a display monitor, printer, storage, etc. Although shown as peripherals of computer platform 102, some or all of storage 108, input device 150 and output device 152 may, in an alternate embodiment, be integrated into computer platform 102.

Various structures and/or buffers (not shown) may reside in memory 106 or may be located in a storage unit separate from the memory 106 in certain embodiments.

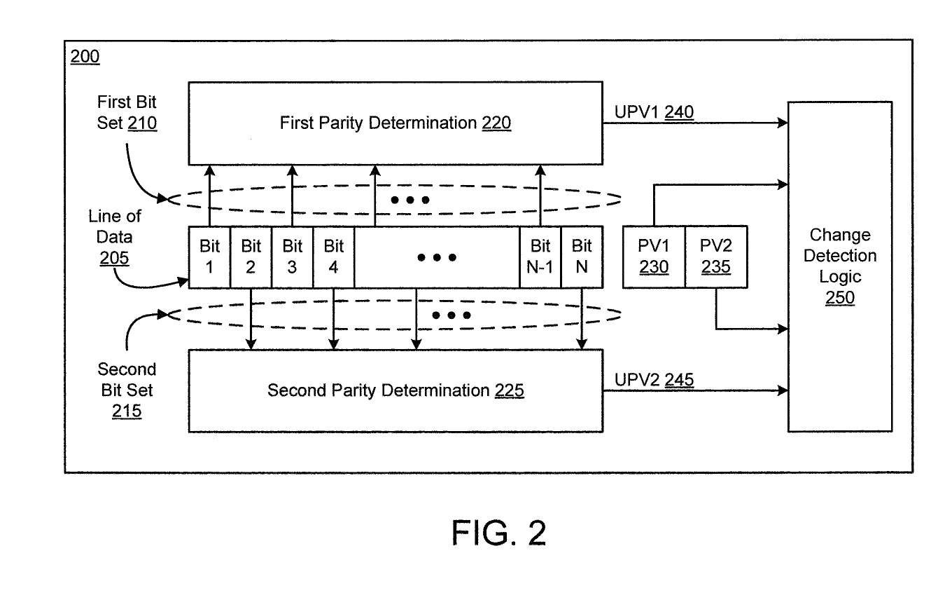

FIG. 2 illustrates select elements of a device 200 to detect for change to information in a line of data according to an embodiment. Device 200 may include a platform such as computer platform 102, for example, a component such as one of those in computer platform 102 or a peripheral device such as one of those of computer environment 100 which is to couple to computer platform 102. For example, device 200 may include storage 108, memory 106, network adapter 128, or a processor of CPU 104 which includes its own internal cache or other storage for a set of bits. Alternatively or in addition, device 200 may include a cache which is to couple to a processing unit such as CPU 104 for providing cache functionality thereto. Alternatively or in addition, device 200 may include a memory controller, I/O controller hub, network adapter, platform controller hub, or other device which includes data storage means.

In an embodiment, device 200 includes a line of data 205 to store a set of bits 1, . . . , N. Although represented as bits 1 through N, it is understood that line of data 205 may include any of a variety of additional of alternative number of bits. The line of data 205 may be a line in any of a variety of components of computer environment 100 which buffers, caches, queues, or otherwise stores bits of data. For example, line of data 205 may include a single register, a single entry in a buffer, cache or queue, or a line (row or column) of data storage cells in an array of data storage cells.

It is also understood that, in various embodiments, the line of data 205 may reside outside of the device 200 which detects for change in that same line of data 205. By way of illustration and not limitation, one component of computing environment 100 (e.g. memory controller 112) may include logic to access and/or determine previous parity information and/or update parity values corresponding to a line of data which is in some other component of computing environment 100 (e.g. memory 106).

As used herein, the word “line” in the term “line of data” refers to a contiguous sequence of data storage cells. The bits stored in line of data 205 may be associated with a single address, e.g. where addressing to access some or all data in the line of data 205 is to be distinguished from addressing to access any other stored data of device 200. Alternatively or in addition, line of a data 205 may be activated by a common read line or a common write line, e.g. where a single read line and/or a single write line activates the memory cells in line of data 205 for an accessing of all data stored therein. Alternatively or in addition, the data stored in line of data 205 may contain a word (e.g. 16-bit, 32-bit, 64-bit, etc.) of data which is stored in line of data 205 as such and/or is to be read from line of data 205 as such.

Line of data 205 may include a first set of bits—e.g. first bit set 210—in bits 1, . . . , N which is distinguished from a second set of bits in bits 1, . . . , N—e.g. second bit set 215. Those bits which are associated with first bit set 210 may differ from those bits which are associated with second bit set 215—e.g. where at least one bit in second bit set 215 is not in first bit set 210, and/or vice versa. The distinction between bits sets may be based, for example, on different logic to access respective bits associated with the different bit sets. It is understood that line of data 205 may include any of a variety of additional or alternative sets of bits in bits 1, . . . , N.

In an embodiment, a parity evaluation for first bit set 210 is distinguished from another parity evaluation for second bit set 215. For example, device 200 may generate, store or otherwise have access to a first parity value PV1 230 corresponding to the bits in line of data 205 which are associated with first bit set 210. Alternatively or in addition, device 200 may generate, store or otherwise have access to a second parity value PV2 235 corresponding to the bits in line of data 205 which are associated with second bit set 215. It is understood that any of a variety of additional or alternative parity values may be determined for multiple bit sets for line of data 205. Either or both of PV1 230 and PV2 235 may be stored in line of data 205, although various embodiments are not limited in this respect.

In an embodiment, PV1 230 and/or PV2 235 may have been calculated by, or otherwise provided to, device 200 as reference values to represent some initial or other reference state of information in line of data 205. For example, PV1 230 and/or PV2 235 may be determined by device 200 in conjunction with data storage device initially calculating or receiving bits 1, . . . , N for storage in line of data 205. More particularly, PV1 230 and/or PV2 235 may represent a state of information which was prior to, concurrent with, or immediately upon storing of that information in line of data 205.

With such reference values, logic of device 200 may detect for a change in information in line of data 205. For example, a first parity determination 220 may be performed by hardware and/or software logic of device 200 to determine a first update parity value UPV1 240 for first bit set 210. Alternatively or in addition, a second parity determination 225 may be performed by other (or the same) hardware logic (e.g. circuitry) and/or software logic (e.g. a program executing on a processor) of device 200 to determine a second update parity value UPV2 245 for second bit set 215.

In an embodiment, PV1 230 and/or PV2 235 may have been calculated by the same logic which performs first parity determination 220 and/or second parity determination 225. Determining a parity value may include, for example, identifying some modulo value (e.g. modulo 2, modulo 3, etc.) for a number which is indicated by bits of a particular bit set. In an embodiment, first parity determination 220 and second parity determination 225 include, respectively, determining whether a number represented by first bit set 210 is odd or even, and determining whether a number represented by second bit set 215 is odd or even.

First parity determination 220 may generate a first update parity value UPV1 240. Alternatively or in addition, second parity determination 225 may generate a second update parity value UPV2 245. As used herein, “update parity value” refers to a parity value which represents a more recent state of information than a comparatively older state of that information—e.g. where the older state is represented by a reference parity value.

An update parity value may be compared to its corresponding reference parity value to determine if any change is indicated for the information on which the update and reference parity values are based. More particularly, with parity values PV1 230 and PV2, and with update parity values UPV1 240 and UPV2 245, change detection logic 250 of device 200 may detect for a change in the information stored in line of data 205. By way of illustration and not limitation, a comparison of PV1 230 and UPV1 240 to one another may indicate some change associated with those of bits 1, . . . , N which are associated with first bit set 210. Similarly, a comparison of PV2 235 and UPV2 245 to one another may indicate some change associated with those of bits 1, . . . , N which are associated with second bit set 215. It is understood that any of a variety of additional or alternative comparisons of update parity values to corresponding reference parity values may be performed, according to various embodiments.

Change detection logic 250 may include any of a variety of hardware logic and/or software logic to evaluate whether a state of first bit set 210 and/or a state of second bit set 210 has changed from some previous state. In an embodiment, change detection logic 250 may provide some output (not shown) to indicate any detected change. For example, the output may be a generic signal to flag that erroneous data in the line of data 205 is indicated—e.g. to indicate that the line of data 205 is now “dirty” or unreliable. Alternatively or in addition, output from change detection logic 250 may identify the changed bit set or bit sets. In an embodiment, the output from change detection logic 250 may be provided to initiate one of various data recovery operations known in the art. For example, the output may be sent to some originating data source and/or to a backup data source to request a correct version of the information in bits 1 through N.

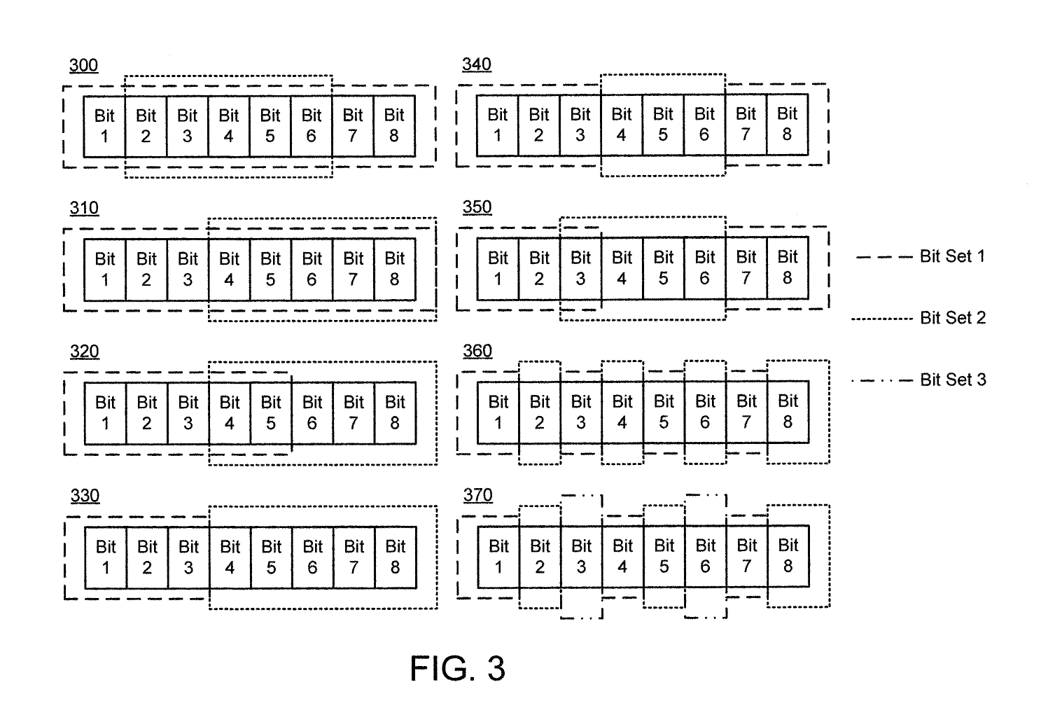

FIG. 3 illustrates select elements of lines of data 300, 310, 320, 330, 340, 350, 360, 370 which each include respective bit sets exhibiting various features according to different embodiments. For the sake of brevity in illustrating features of various embodiments, lines of data 300, 310, 320, 330, 340, 350, 360, 370 are each shown including respective bits 1, . . . , 8. However, it is understood that, in various embodiments, respective features of lines of data 300, 310, 320, 330, 340, 350, 360, 370 may each be extended to apply to lines of data which include any of a variety of additional or alternative numbers of bits.

Bits in lines of data 300, 310, 320, 330, 340, 350, 360, 370 may be variously associated with different sets of bits—e.g. where a first bit set (and/or a parity evaluation thereof) is to be distinguished from a second bit set (and/or a parity evaluation thereof). By way of illustration and not limitation, the allocation of bits to different bit sets in one or more of lines of data 300, 310, 320, 330, 340, 350, 360, 370 may be characteristic in one or more ways of the allocation of various bits to different bit sets in line of data 205.

It is understood that references to a “first bit set”, “second bit set”, “third bit set”, etc. in the discussion of FIG. 3 are generic across lines of data 300, 310, 320, 330, 340, 350, 360, 370. More particularly, it is understood that a first, second, third, etc. bit set of one line of data in FIG. 3 is not necessarily the same first, second, third, etc. bit set of some other line of data in FIG. 3.

In an embodiment, one bit set in a line of data may completely overlap another bit set in a line of data. For example, a first bit set in line of data 300 includes bits 1 through 8, completely overlapping a second bit set in line of data 300 which includes bits 2 through 6. In another example, a first bit set in line of data 310 includes bits 1 through 8, and a second bit set in line of data 310 includes bits 4 through 8.

Additionally or alternatively, each bit set in a line of data may include a bit which is not in another bit set in a line of data. For example, a first bit set in line of data 320 includes bits 1 through 5, and a second bit set in line of data 320 includes bits 4 through 8.

Additionally or alternatively, each bit in a line of data may be associated with only one bit set. For example, a first bit set in line of data 330 includes bits 1 through 3, and a second bit set in line of data 330 includes bits 4 through 8. It is noted that lines of data 300, 310, 320, 330 all demonstrate bit sets which each comprise contiguous bits of their respective lines of data.

Additionally or alternatively, bits in a bit set may include non-contiguous bits in a line of data—e.g. where bits in one bit set are on either side of another bit which is not in that bit set, but which is rather in a different bit set. For example, a first bit set in line of data 340 includes bits 1 through 3, 7 and 8, while a second bit set in line of data 340 includes bits 4 through 6.

In various embodiments, the allocating of bits in a line of data to different bit sets may exhibit some combination of the features discussed above. One bit set in a line of data may, for example, include non-contiguous bits of the line of data, while different bit sets at least partially overlap one another. As an illustration, a first bit set in line of data 350 includes bits 1 through 3, 7 and 8, and a second bit set in line of data 350 includes bits 3 through 6.

Additionally or alternatively, for a sequence of some bits in a line of data, successive bits in the sequence may each be in a different bit set than that of the immediately preceding bit in the sequence. For example, the “odd bits” 1, 3, 5, 7 in line of data 360 belong to a first bit set, and the “even” bits 2, 4, 6, 8 in line of data 360 belong to a second bit set.

In various embodiments, the bits in the line of the data storage device may be variously allocated to more than two sets of bits. The various allocating of bits to more than two bit sets may exhibit some combination of various features discussed above with respect any two given bit sets. By way of illustration and not limitation, for a sequence of some bits in a line of data, successive bits in the sequence may each be in a different one of three (or more) bit sets than that of the immediately preceding bit in the sequence. For example, bits 1, 4, and 7 in line of data 370 belong to a first bit set, bits 2, 5 and 8 in line of data 370 belong to a second bit set, and bits 3 and 6 in line of data 370 belong to a third bit set.

Particularly effective protection from MBU soft errors is provided for bits in a line of data where the allocation of one bit to one or more bit sets differs from the bit set allocation of an adjacent bit. Where bit set allocation for one bit differs from bit set allocation for an adjacent bit, an instance of adjacent bits being flipped due to a single MBU soft error particle event will nevertheless be detected by changes to two or more different parity values for different respective bit sets. Accordingly, increasing variation in bit set allocations for a line of data—esp. the sequential varying of bit set allocation such as in lines of data 360, 370—incrementally improves the ability to detect MBU soft errors with multiple parity values for the line of data.

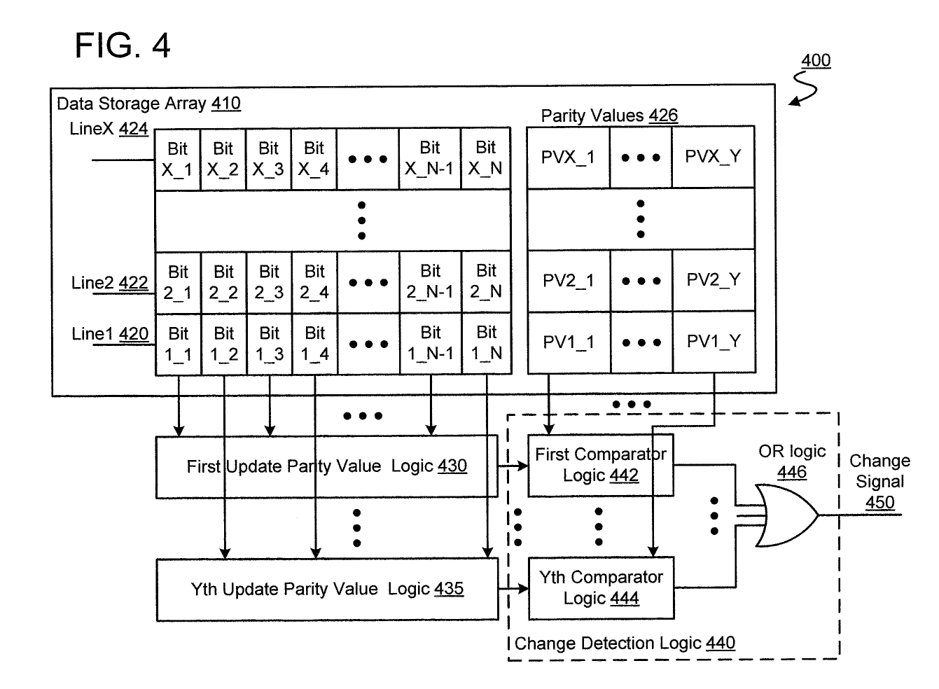

FIG. 4 illustrates select elements of a data storage device 400 to detect for change to information in a line of data according to an embodiment. Data storage device 400 may include some or all of the features of device 200, for example. Data storage device 400 may include a data storage array 410 having lines of data Line1 420, Line2 422, . . . , LineX 424, some or all of which may include features of line of data 205, for example. In an embodiment, Line1 420, Line2 422, . . . , LineX 424 each include N respective bits which are variously associated with two of more bit sets for that line of data. It is understood that data storage array 410 may include any of a variety of additional or alternative lines of data (or a single line of data instead of memory array 410), and that the lines of data in data storage array 410 may include various alternative numbers of bits, according to various embodiments.

Features of various embodiments are discussed herein in terms of Line1 420. It is understood that such features may be extended to also apply to some or all other lines of data storage array 410. In an embodiment, Line1 420 includes bits 1_1, . . . 1_N, various bits of which are each associated different respective ones of Y bit sets, where Y is an integer which is greater than one (1). Detection of changes to information in a line of data may improve with larger values for Y. Each of Line2 422, . . . , LineX 424 may similarly include bits which are variously associated with different bit sets. The associating of bits in one, some or each of Line1 420, Line2 422, . . . , LineX 424 with different bit sets may exhibit various features discussed with respect to FIG. 3, for example.

In an embodiment, a parity evaluation for a first bit set of Line1 420 is distinguished from another parity evaluation for a different bit set—e.g. the Yth bit set—of Line1 420. For example, data storage device 400 may include parity values 426 including at least a pair of parity values for each of the lines of data of data storage array 410. In an embodiment, parity values 426 for a given line of data includes a parity value for each bit set of that line of data—e.g. from a first parity value PV1_1 corresponding to a first bit set in Line1 420 to a Yth parity value PV1_Y corresponding to a Yth bit set in Line1 420. It is understood that parity values 426 may include various alternative or additional parity values for Line1 420. Some or all of PV1_1, . . . , PV1_Y may be stored in Line1 420 with bits 1_1, . . . , 1_N, although various embodiments are not limited in this regard.

Some or all of PV1_1, . . . , PV1_Y may be used as reference parity values in detecting for a change in Line1 420. For example, data storage device 400 may include first update parity value logic 430 to determine a first update parity value based on a first bit set in Line1 420. Alternatively or in addition, data storage device 400 may include additional update parity value logic for others of the Y bits sets for Line1 420—e.g. up to a Yth update parity value logic 435 to determine a Yth update parity value based on a Yth set in Line1 420.

In an embodiment, data storage device includes circuitry to multiplex between Line1 420, Line2 422, . . . , LineX 424 to variously provide respective bits from any given line of data to first update parity value logic 430, . . . , Yth update parity value logic 435.

Although an illustrative bit set in bits 1_1, . . . , 1_N is shown being provided to first update value logic 430, and another illustrative bit set in bits 1_1, . . . , 1_N is shown being provided to Yth update value logic 435, it is understood that various other parity evaluations for alternative and/or additional (e.g. third, fourth, etc.) bit sets may be performed for Line1 420, according to various embodiments. In an embodiment, the same update parity value circuitry is used to perform an update parity value determination for different bit sets of a given line of data.

Data storage device 400 may include change detection logic 440 to receive update parity values from each of first update parity value logic 430, . . . , Yth update parity value logic 435. First comparator logic 442 of change detection logic 440 may compare reference parity value PV1_1 with the update parity value for the first bit set of Line1 420. Similarly, additional comparator logic of change detection logic 440—for others of the Y bit sets—may compare other update parity values from first update parity value logic 430, . . . , Yth update parity value logic 435 each to corresponding reference parity values. For example, Yth comparator logic 444 may compare reference parity value PV1_Y with the update parity value for the Yth bit set of Line1 420. Comparing a reference parity value with a corresponding update parity value may include, for example, identifying whether a difference between the two parity values is a non-zero value.

In an embodiment, first comparator logic 442, . . . , Yth comparator logic 444 may each provide respective outputs indicating results of their respective parity value comparisons. For example, change detection logic 440 may include OR logic 446 to combine the respective outputs of first comparator logic 442, . . . , Yth comparator logic 444. The OR logic 446 may output a change signal 450 which indicates a change if any parity value comparison by first comparator logic 442, . . . , Yth comparator logic 444 indicates a change in Line1 420. Additionally or alternatively, change detection logic 440 may provide an output identifying which bit set (or bit sets) have data which has changed since a previous state associated with the reference parity values PV1_1, . . . , PV1_Y.

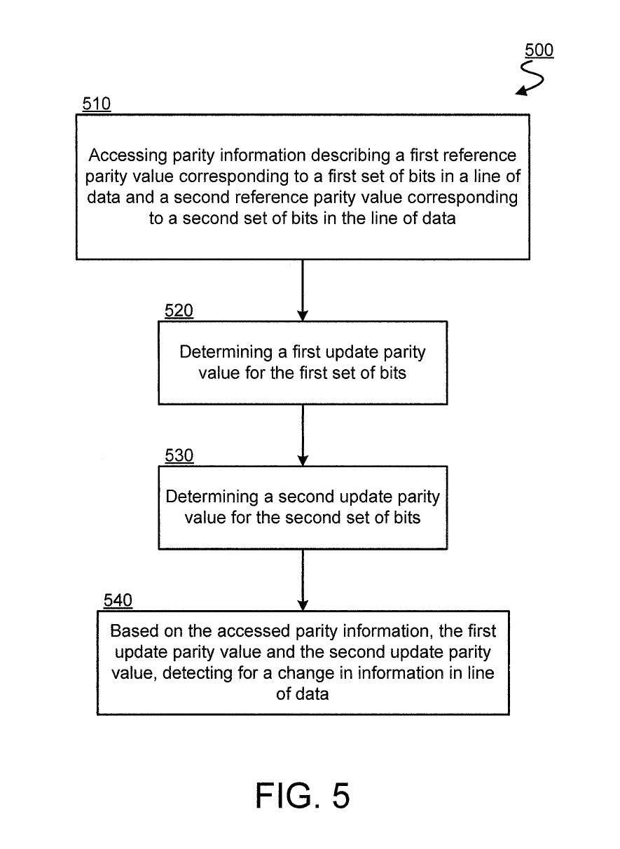

FIG. 5 illustrates select elements of a method 500 to identifying, according to an embodiment, whether a line of data has been changed. Method 500 may be performed by device 200, for example.

Method 500 may include, at 510, accessing parity information describing a first reference parity value corresponding to a first bit set in a line of data and a second reference parity value corresponding to a second bit set in the line of data. In an embodiment, the first set of bits includes a bit which is not in the second set of bits. The accessed parity information may specify or otherwise indicate a first reference parity value corresponding to the first set of bits and a second reference parity value corresponding to the second set of bits. The parity values indicated by the accessed parity information may include reference parity values to be compared to corresponding update parity values for the line of data.

Method 500 may further include, at 520, determining a first update parity value for the first bit set. Additionally or alternatively, method 500 may include, at 530, determining a second update parity value for the second bit set. Based on the accessed parity information, the first update parity value and the second update parity value, method 500 may, at 540, detect for a change in line of data.

In an embodiment, the detecting for a change in line of data includes determining that the change has occurred if either (1) a difference between the first reference parity value and the first update parity value is identified, or (2) a difference between the second reference parity value and the second update parity value is identified. In various embodiments, an output signal may then be transmitted and/or a value stored in memory to represent a result of the detecting for a change in line of data.

Techniques and architectures for detecting for an error in stored data are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and each coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A method comprising:
accessing parity information for a line of data of a data storage device, the line of data including a first set of bits and a second set of bits, wherein the first set of bits includes a bit which is not in the second set of bits, the parity information describing a first reference parity value corresponding to the first set of bits and a second reference parity value corresponding to the second set of bits;
determining a first update parity value for the first set of bits;
determining a second update parity value for the second set of bits;
detecting for a change to information in the line of data, the detecting based on the accessed parity information, the first update parity value and the second update parity value; and
generating an output signal indicating a result of the detecting for the change to the information in the line of data.

2. The method of claim 1, wherein the bit in the first set of bits is adjacent to a bit in the second set of bits.

3. The method of claim 1, wherein the first set of bits further includes a second bit, where a third bit between the bit and the second bit is not in the first set of bits, wherein the second set of bits includes the third bit.

4. The method of claim 3, wherein successive bits of the data along the line of data are each in an alternate one of the first set of bits and the second set of bits.

5. The method of claim 1, further comprising calculating one of the first reference parity value and the second reference parity value.

6. The method of claim 1, wherein line of data is a line in an array of data storage cells.

7. The method of claim 1, wherein the line of data is activated by a common read line or a common write line of the data storage device.

8. The method of claim 1, wherein the detecting for the change to the information includes determining that the change has occurred if:
a difference between the first reference parity value and the first update parity value is identified, or
a difference between the second reference parity value and the second update parity value is identified.

9. A device comprising:
circuitry to access parity information for a line of data of a data storage device, the line of data including a first set of bits and a second set of bits, wherein the first set of bits includes a bit which is not in the second set of bits, the parity information describing a first reference parity value corresponding to the first set of bits and a second reference parity value corresponding to the second set of bits;
circuitry to determine a first update parity value for the first set of bits;
circuitry to determine a second update parity value for the second set of bits; and
circuitry to detect for a change to information in the line of data, the detecting based on the accessed parity information, the first update parity value and the second update parity value.

10. The device of claim 9, wherein the first set of bits further includes a second bit, where a third bit between the bit and the second bit is not in the first set of bits, wherein the second set of bits includes the third bit.

11. The device of claim 10, wherein successive bits of the data along the line of data are each in an alternate one of the first set of bits and the second set of bits.

12. The device of claim 9, wherein the line of data is activated by a common read line or a common write line of the data storage device.

13. The device of claim 9, wherein the detecting for the change to the information includes determining that the change has occurred if:
a difference between the first reference parity value and the first update parity value is identified, or
a difference between the second reference parity value and the second update parity value is identified.

14. The device of claim 9, further comprising circuitry to calculate one of the first reference parity value and the second reference parity value.

15. A data storage device comprising:
a line of data to store a plurality of bits including a first set of bits and a second set of bits, wherein the first set of bits includes a bit which is not in the second set of bits;
circuitry to access parity information for the line of data, the parity information describing a first reference parity value corresponding to the first set of bits and a second reference parity value corresponding to the second set of bits;
circuitry to determine a first update parity value for the first set of bits;
circuitry to determine a second update parity value for the second set of bits; and
circuitry to detect for a change to information in the line of data, the detecting based on the accessed parity information, the first update parity value and the second update parity value.

16. The data storage device of claim 15, wherein the first set of bits further includes a second bit, where a third bit between the bit and the second bit is not in the first set of bits, wherein the second set of bits includes the third bit.

17. The data storage device of claim 16, wherein successive bits of the data along the line of data are each in an alternate one of the first set of bits and the second set of bits.

18. The data storage device of claim 15, wherein the line of data is activated by a common read line or a common write line of the data storage device.

19. The data storage device of claim 15, wherein the detecting for the change to the information includes determining that the change has occurred if:
a difference between the first reference parity value and the first update parity value is identified, or
a difference between the second reference parity value and the second update parity value is identified.

20. The data storage device of claim 15, further comprising circuitry to calculate one of the first reference parity value and the second reference parity value.
